(19) United States
(12) Patent Application Publication
(10) Pub. No.: US 2026/0304818 A1
(43) Pub. Date: Oct. 1, 2026

(54) CONVERSION OF METAL/METAL OXIDE MATERIALS TO SEMICONDUCTING TRANSITION METAL DICHALCOGENIDE MATERIALS IN GATE-ALL-AROUND (GAA) TRANSISTOR DEVICES

(71) Applicant: Intel Corporation, Santa Clara, CA (US)

(72) Inventors: Rambert Nahm, Beaverton, OR (US); Natalie Briggs, Hillsboro, OR (US); Kirby Maxey, Hillsboro, OR (US); Azimkhan Kozhakhmetov, Portland, OR (US); Carl Hugo Naylor, Portland, OR (US); Jessica M. Torres, Portland, OR (US); Matthew V. Metz, Portland, OR (US)

(73) Assignee: Intel Corporation, Santa Clara, CA (US)

(21) Appl. No.: 19/094,153

(22) Filed: Mar. 28, 2025

(51) Int. Cl. H10D 30/47; H01L 21/383; H10D 30/00; H10D 30/01; H10D 62/80; H10D 84/83; H10D 84/85

(52) U.S. Cl. CPC H10D 30/481; H10D 30/017; H10D 30/0193; H10D 30/502; H10P 32/12; H10P 32/17; H10D 62/883; H10D 84/8311; H10D 84/851

(57) ABSTRACT

In some embodiments, a gate-all-around (GAA) transistor device includes channels comprising transition metal dichalcogenide materials. The channels are formed by converting metal or metal oxide material layers (which include, e.g., molybdenum or tungsten) of a material stack into the transition metal dichalcogenide material during a transistor fabrication process. The conversion may be performed by heating the metal/metal oxide material layers of the stack in the presence of a gas comprising, for example, sulfur, selenium, or tellurium, during the transistor fabrication process.

### BACKGROUND

Recently, chalcogenide materials have been of interest as channel materials in gate-all-around (GAA) transistor devices, e.g., nanowire or nanoribbon transistor devices. However, current techniques for fabricating transistor devices with these materials as channel materials is complex, with some techniques requiring multiple layer transfers of chalcogenide material grown on a first wafer to a separate second wafer.

### BRIEF DESCRIPTION OF THE DRAWINGS

FIG. 1 illustrates a perspective view of an example gate-all-around (GAA) transistor.

FIGS. 2A-2G illustrate an example process of forming a gate-all-around (GAA) transistor device in accordance with embodiments herein.

FIGS. 3A-3E illustrate an example process of forming a complementary gate-all-around (GAA) transistor device in accordance with embodiments herein.

FIGS. 4A-4H illustrate another example process of forming a complementary gate-all-around (GAA) transistor device in accordance with embodiments herein.

FIG. 5 is a top view of a wafer and dies that may include any of the embodiments disclosed herein.

FIG. 6 is a cross-sectional view of an integrated circuit device that may include any of the embodiments disclosed herein.

FIG. 7 is a cross-sectional view of an integrated circuit device assembly that may include any of the embodiments disclosed herein.

FIG. 8 is a block diagram of an example electrical device that may include any of the embodiments disclosed herein.

### DETAILED DESCRIPTION

Embodiments of the present disclosure include transition metal dichalcogenide materials (which may sometimes be referred to as “2D materials”) as channel materials in gate-all-around (GAA) transistor devices. In particular embodiments, nanowire templates may be formed using techniques that are similar to silicon-based GAA fabrication processes and with fab-compatible materials. For example, the nanowire templates may be formed from metal/metal oxide materials that include, e.g., molybdenum or tungsten. The nanowire templates are then converted to transition metal dichalcogenide materials (also referred to herein as “2D materials”) during fabrication, e.g., by heating the templates in the presence of a gas comprising, for example, sulfur, selenium, or tellurium.

The techniques described herein can enable complementary GAA structures comprising stacked n-type and p-type transistor devices in a straightforward manner. In addition, techniques herein might not require blanket growth, layer transfer, nor 2D material patterning as in previous techniques, allowing for the fabrication of GAA structures with 2D materials, which previously may have required multiple layer transfers of 2D material grown on separate 300 mm wafers to a single wafer. Accordingly, embodiments herein may remove the burden of growing 300 mm-scale crystals.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

It is to be understood that drawings illustrate idealized versions of structure cross-sections. In actual cross-sections, the lines, layers, and other elements illustrated in the drawings can have shapes that vary from those illustrated. For example, surfaces illustrated as planar possess undulations, bumps, or dishing features; sidewalls can have a taper to them; ninety-degree corners can be rounded; and lines, layers, and features can overlap more or less than illustrated.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

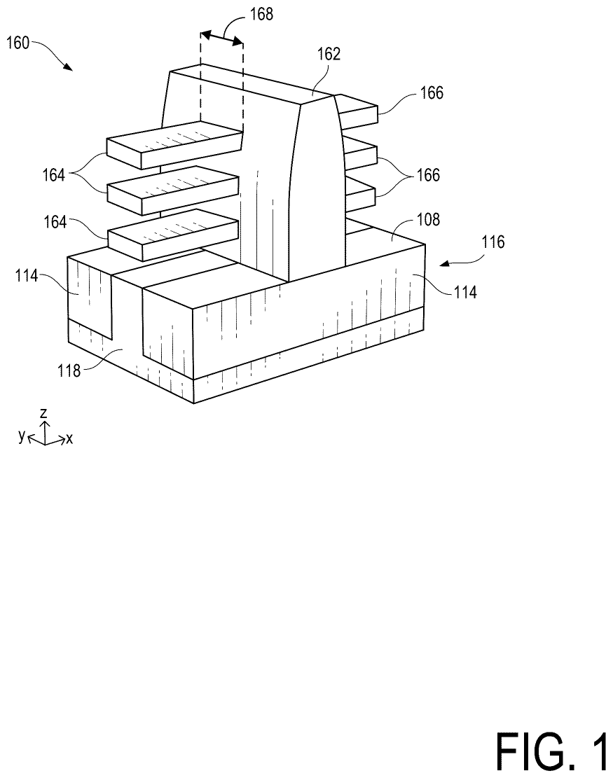

FIG. 1 is a perspective view of an example gate-all-around (GAA) transistor 160. The transistor 160 is formed on a substrate 116 having a substrate surface 108 and a bulk region 118. Isolation regions 114 separate the source and drain regions of the transistor from other transistors. The example transistor 160 is a stacked GAA transistor, whereby the gate 162 controls current flow between multiple source regions 164 and multiple drain regions 166. As shown, the source regions 164 and drain regions 166 are elevated above the bulk region 118, and the transistor 160 is considered to be a “gate-all-around” transistor because the gate 162 encompass all sides of the channel regions that extend from the source regions 164 to the drain regions 166. In some instances, the transistor 160 can alternatively be referred to as a nanowire, nanosheet, or nanoribbon transistor, depending on the width 168 and/or shape of the channel regions extending through the gate 162. While the examples described herein are with respect to gate-all-around (GAA) transistor devices, it will be understood that the same or similar concepts can be applied to the fabrication of other types of transistor devices, e.g., FinFET transistor devices.

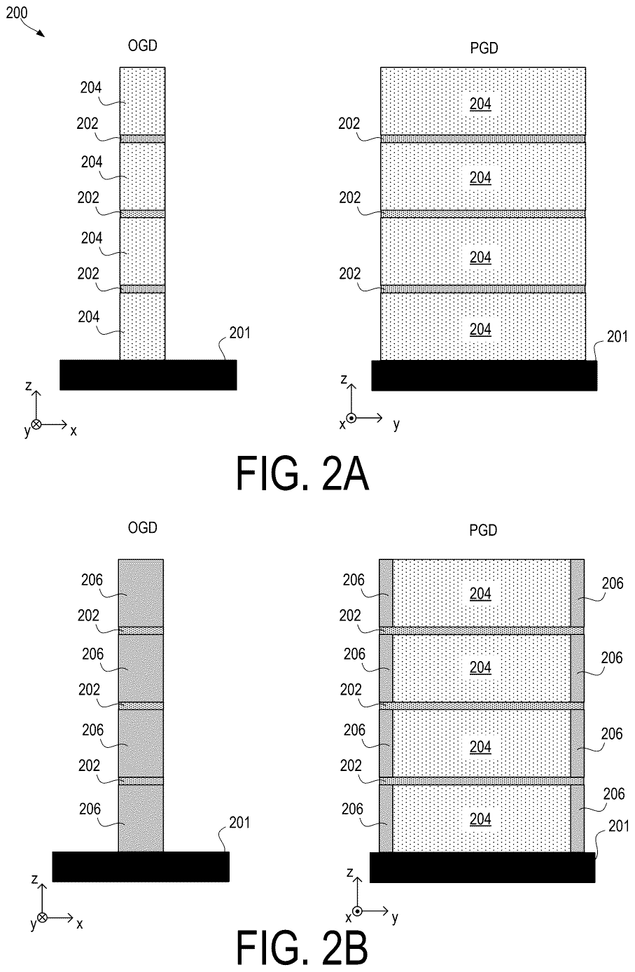

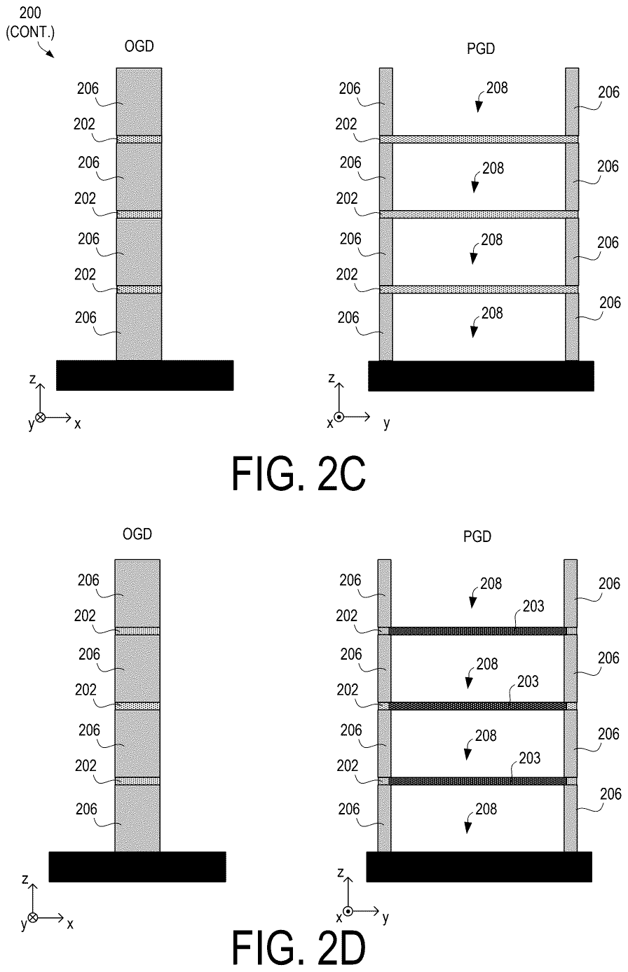

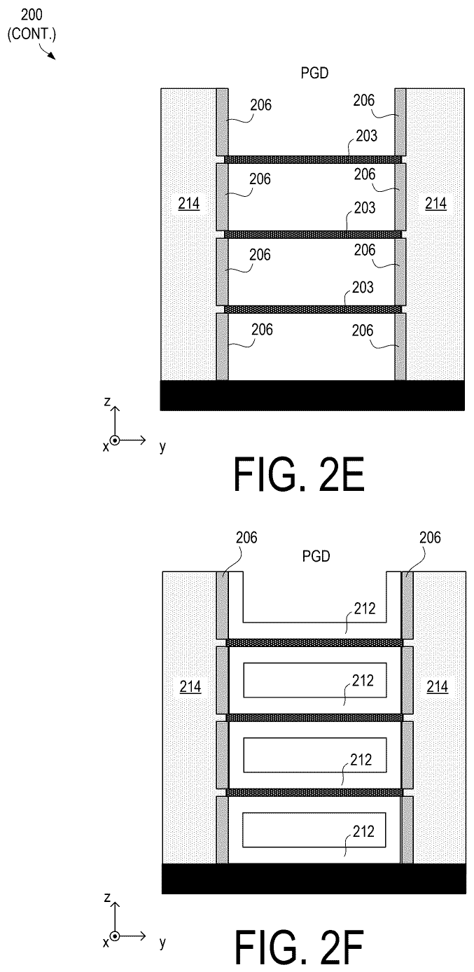

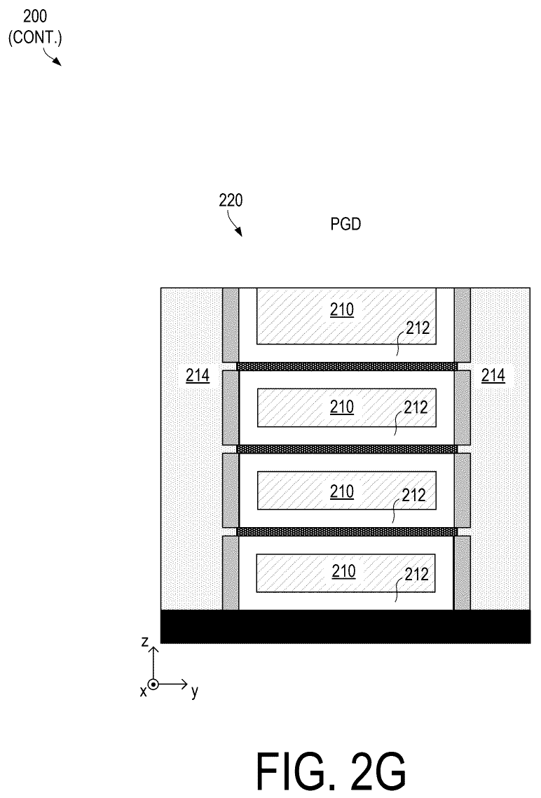

FIGS. 2A-2G illustrate an example process 200 of forming a gate-all-around (GAA) transistor device in accordance with embodiments herein. In particular, FIGS. 2A-2G illustrate cross-sectional profile views, in both the orthogonal-to-gate direction (OGD) and parallel-to-gate direction (PGD), as labeled, of GAA channel formation in accordance with some embodiments, including conversion of metal/metal oxide material to a dichalcogenide material.

Accordingly, FIGS. 2A-2G show possible examples of intermediate structures during the process described below. The example process 200 may include fewer, additional, or other operations than those shown, and the operations of the process 200 can be performed in another order than shown. Moreover, some of the operations shown or described as being separate may be performed simultaneously, while some of the operations shown or described as being performed at the same time may be performed at different times. Although the process 200 illustrates the formation of a certain number of nanoribbon or nanowire channel regions, any number of GAA channel regions can be formed using the process 200.

The example process 200 begins with a superlattice stack formed on a substrate 201 as shown in FIG. 2A. The superlattice stack includes alternating layers 204 of sacrificial material and layers 202 of metal or metal oxide material. The layers 202 will be used as channels in the resulting transistor device. The sacrificial material may include, for example, silicon-based oxide materials (e.g., silicon oxide (SiOₓ)), silicon-based nitride materials (e.g., silicon nitride (SiNₓ)), polysilicon, or other types of metal oxides or metal materials. The layers 202 may include molybdenum or tungsten, and in some embodiments, may further include oxygen. For example, the layers 202 may include a molybdenum-or tungsten-based oxide (e.g., MoOₓ or WOₓ). Dimple regions 206 can then be formed on opposite sides of the sacrificial material layers 204 in the PGD direction, as shown in FIG. 2B. In certain embodiments, the dimple regions 206 may be a dielectric material.

The layers 202 are then released as shown in FIG. 2C, e.g., by selectively etching the sacrificial material in the layers 204, leaving space 208 as shown in FIG. 2C where the sacrificial material was previously. The stack may then be heated in the presence of a chalcogen gas to convert the exposed metal or metal oxide material in the layers 202 into a 2D material. For example, in some embodiments, the stack shown in FIG. 2C may be heated in the presence of a gas comprising one or more of sulfur (e.g., H₂S), tellurium (e.g., H₂Te), selenium (e.g., H₂Se), or other suitable chalcogen gases. In other embodiments, the stack may be heated in the presence of a gas comprising organometallics, such as, for example, di-tert-butyl sulfide, di-isopropyl selenide, diethyl telluride. This may cause at least a portion of the exposed areas in the layers 202 to convert to a 2D material 203, which may be, for example, MoS₂, WS₂, MoSe₂, MoTe₂, or WSe₂ in certain embodiments. The 2D material 203 may become the channel region of the transistor device produced by the process 200. In some embodiments, the process may be used to produce MoS₂, WS₂, MoSe₂, MoTe₂ channel regions for n-type transistor devices, while in other embodiments, the process may be used to produce WSe₂ channel regions for p-type transistor devices. In some cases, only the outer portions of the exposed areas of the layers 202 may convert into 2D material 203, while in other cases, the entire thickness of the layers 202 may convert. In some embodiments, some or all of the portions of the layers 202 between the dimple regions 206 may also convert into a 2D material 203 during this process. In some embodiments, the resulting 2D materials 203 may be etched to reduce their thickness.

After the channels have been converted into 2D materials, a “gate-last” process as shown in FIGS. 2E-2F can be performed to yield the finished transistor device 220 shown in FIG. 2G. In particular, the distal ends of the layers 202, which might have not converted into 2D material 203 in the previous operations, may be etched away or otherwise removed and source/drain regions 214 can be formed on either side of the stack as shown in FIG. 2E. Then, gate dielectric 212 can be formed around the 2D material 203 as shown in FIG. 2F, and the gate material 210 can be formed around the gate dielectric 212 to yield the transistor device 220 shown in FIG. 2G.

Although shown as being formed in the process after the 2D material conversion described above, the source/drain regions 214 may also be performed in another portion of the fabrication process. For example, in some embodiments, the source/drain regions 214 may be formed after formation of the dimple regions 206 and before release of the layers 202 (e.g., deposited on opposite ends of the stack shown in FIG. 2B and before the release of the layers 202 as shown in FIG. 2C).

In other embodiments, a “gate-first” process can be performed to yield substantially the same finished transistor device 220 as shown in FIG. 2G. In such a process, the gate dielectric 212 can be formed on the 2D material 203 of the stack shown in FIG. 2D and gate material 210 then formed around the gate dielectric 212. The source/drain regions 214 would then be formed on either side of the stack to yield substantially the same transistor device 220 shown in FIG. 2G.

The resulting transistor device 220 can then be implemented in a logic circuit or other type of electronic assembly or system, e.g., those described below. Embodiments herein may further be used to fabricate a complementary field effect transistor (CFET) device. For instance, to scale to a CFET device, a taller superlattice may be used with different metal/metal oxide layers for the p-type and n-type channels. A single conversion of the channel material can then be performed, with two distinct 2D materials being formed with the same chalcogen gas. For instance, one set of resulting channels can be a material that might be better suited for p-type use (e.g., WSe2) while another set of resulting channels can be a material that might be better suited for n-type use (e.g., MoSe₂).

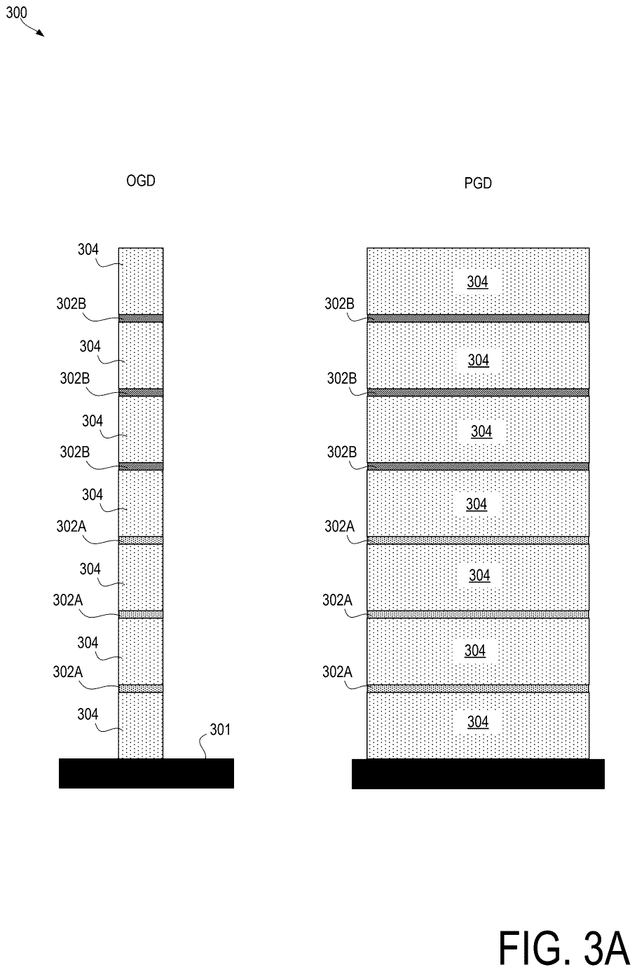

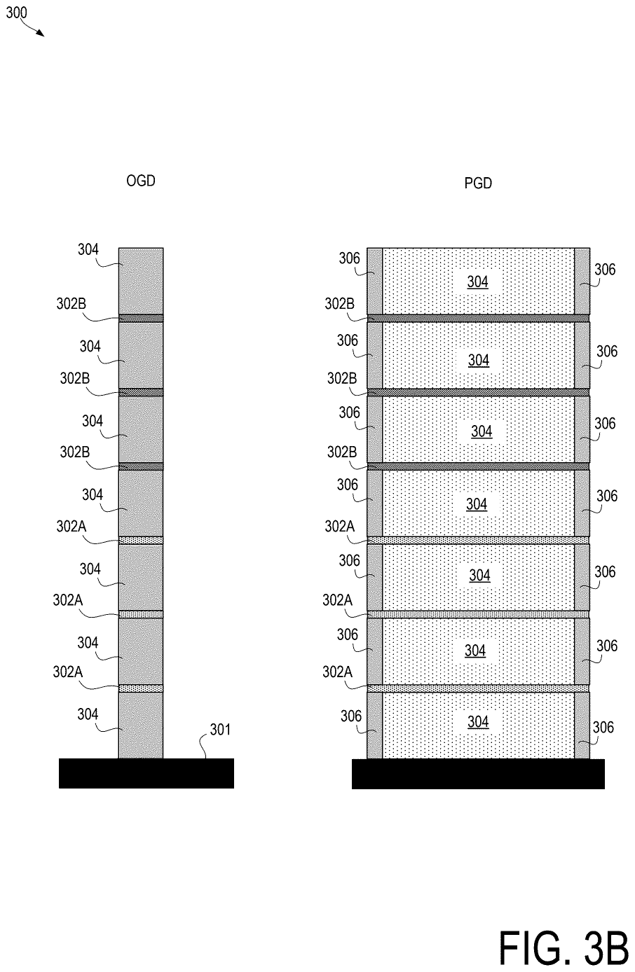

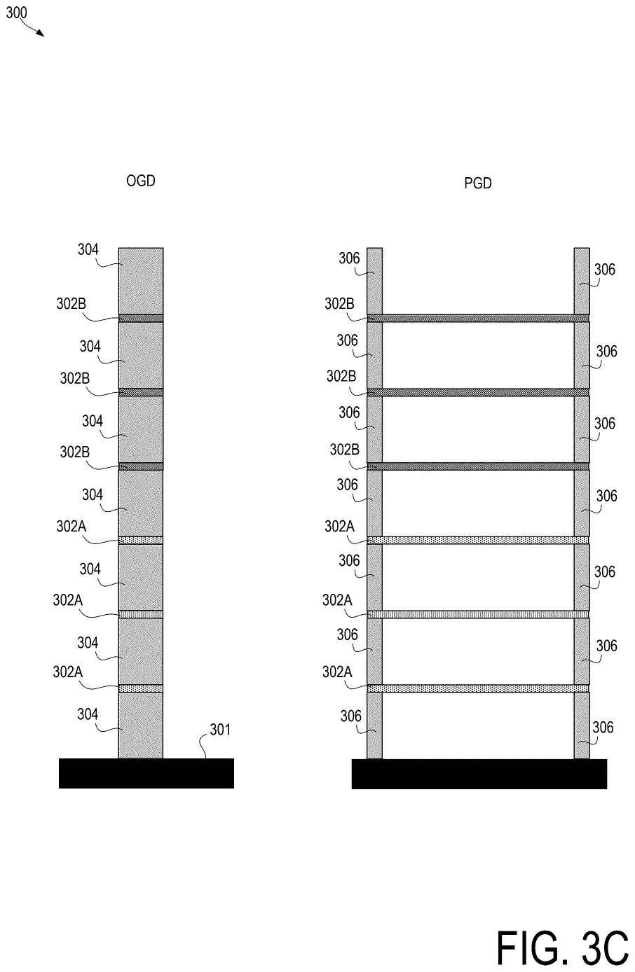

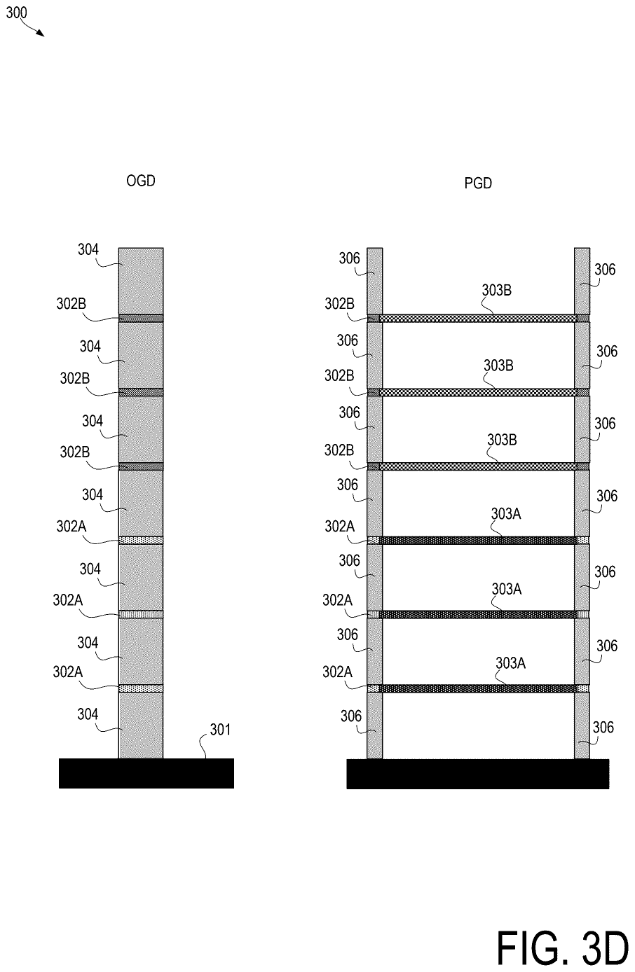

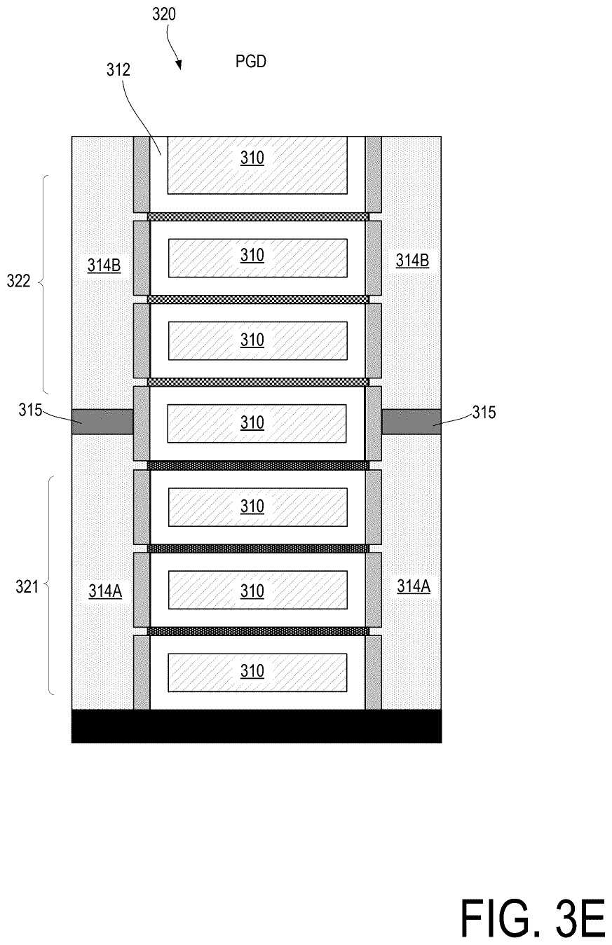

FIGS. 3A-3E illustrate an example process 300 of forming a complementary gate-all-around (GAA) transistor device in accordance with embodiments herein. FIGS. 3A-3D illustrate cross-sectional profile views as in the previous example, in both the OGD and PGD directions, as labeled. Similarly, FIGS. 3A-3E show possible examples of intermediate structures during the process described below. The example process 300 may include fewer, additional, or other operations than those shown, and the operations of the process 300 can be performed in another order than shown. Moreover, some of the operations shown or described as being separate may be performed simultaneously, while some of the operations shown or described as being performed at the same time may be performed at different times. Although the process 300 illustrates the formation of a certain number of nanoribbon or nanowire channels, any number of GAA channels can be formed using the process 300.

The process 300 begins similarly to the process 200, with a superlattice stack formed on a substrate 301 as shown in FIG. 3A. The superlattice stack includes alternating layers of sacrificial material (layers 304) and layers of metal or metal oxide material (layers 302A, 302B). The sacrificial material layers may be formed of the same or similar materials described in the previous example. However, in the example shown, the layers 302A of a first metal/metal oxide material and layers 302B of a second (different) metal/metal oxide material. The first and second metal/metal oxide materials may include molybdenum or tungsten, and in some embodiments, may further include oxygen. For example, the layers 302A, 302B may include a molybdenum-or tungsten-based oxide (e.g., MoOₓ or WOₓ).

Dimple regions are then formed on opposite sides of the sacrificial material layers 304 (in the PGD direction) as shown in FIG. 3B. The layers 302A, 302B may then be released as in the previous example, as shown in FIG. 3C, and the stack may be heated in the presence of a chalcogen gas to convert the exposed metal/metal oxide materials in the layers 302A, 302B into 2D materials. For example, in some embodiments, the stack shown in FIG. 3C may be heated in the presence of a gas comprising one or more of sulfur (e.g., H₂S), tellurium (e.g., H₂Te), selenium (e.g., H₂Se), or other suitable chalcogen gases. In other embodiments, the stack may be heated in the presence of a gas comprising organometallics, such as, for example, di-tert-butyl sulfide, di-isopropyl selenide, diethyl telluride. This may cause the exposed areas 303A, 303B in the layers 302A, 302B, respectively to convert to 2D materials. For example, the areas 303A may be converted into one of MoS₂, WS₂, MoSe₂, MoTe₂ for use as an n-type transistor device, while the areas 303B may be converted into WSe₂ for use as a p-type transistor device. In some cases, only the outer portions of the exposed areas 303A, 303B may convert, while in other cases, the entire thickness of the exposed areas 303A, 303B may convert. In some embodiments, some or all of the portions of the layers 302A, 302B between the dimple regions 306 may also convert into a 2D material during this process. In some embodiments, the resulting 2D material layers 302A, 302B may be etched to reduce their thickness.

After the channels have been converted into 2D materials, a gate-last process or a gate-first process similar to the ones described above can be performed to form the source/drain regions 314A, 314B for the transistors 321, 322 (which are separated by a layer 315, which may be dielectric in some embodiments or metal in other embodiments (e.g., to conductively couple the source/drain regions)), respectively, as well as the gate dielectric 312, and the gate 310, and yield the CFET device 320 of FIG. 3E, which include an n-type transistor 321 and p-type transistor 322. The CFET device 320 can then be implemented in a logic circuit or other type of electronic assembly or system, e.g., those described below.

In some embodiments, the two sets of channels in the CFET stack can be converted in two passes, with different chalcogens, e.g., by blocking one set of the channels with patterning and converting the exposed set of wires, and then performing the same with the other set of channels (i.e., blocking the already-converted channels and then converting the other set). This can be done with channels of the same metal/metal oxide material for the different channel/transistor types, as illustrated and described below, or with channels of different metal/metal oxide material.

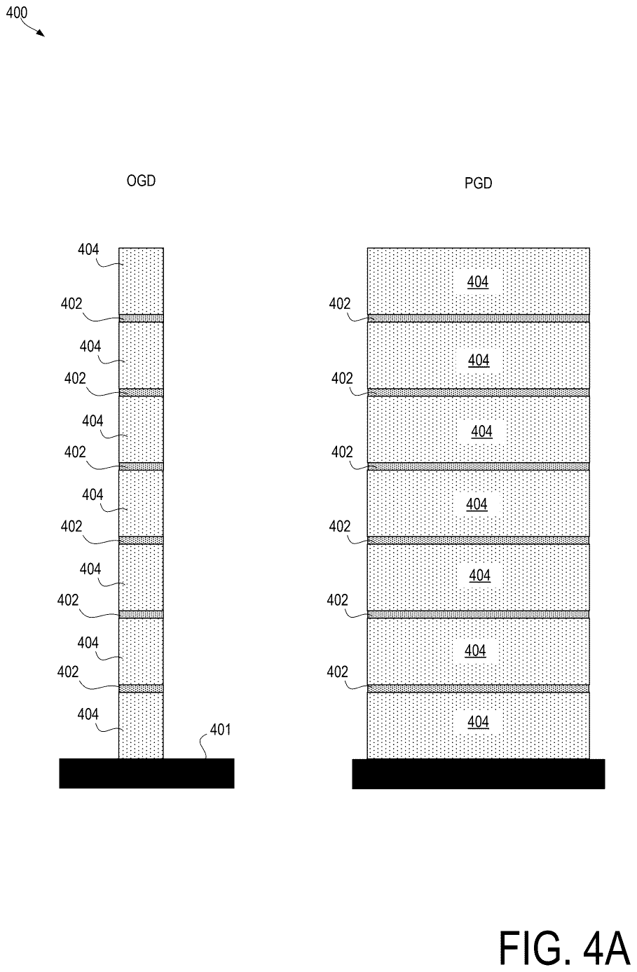

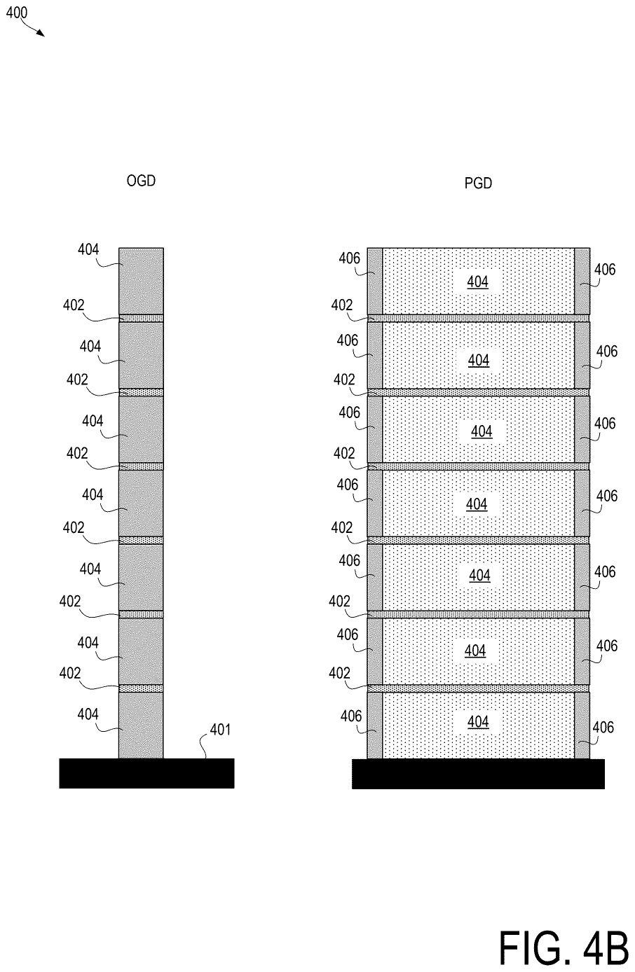

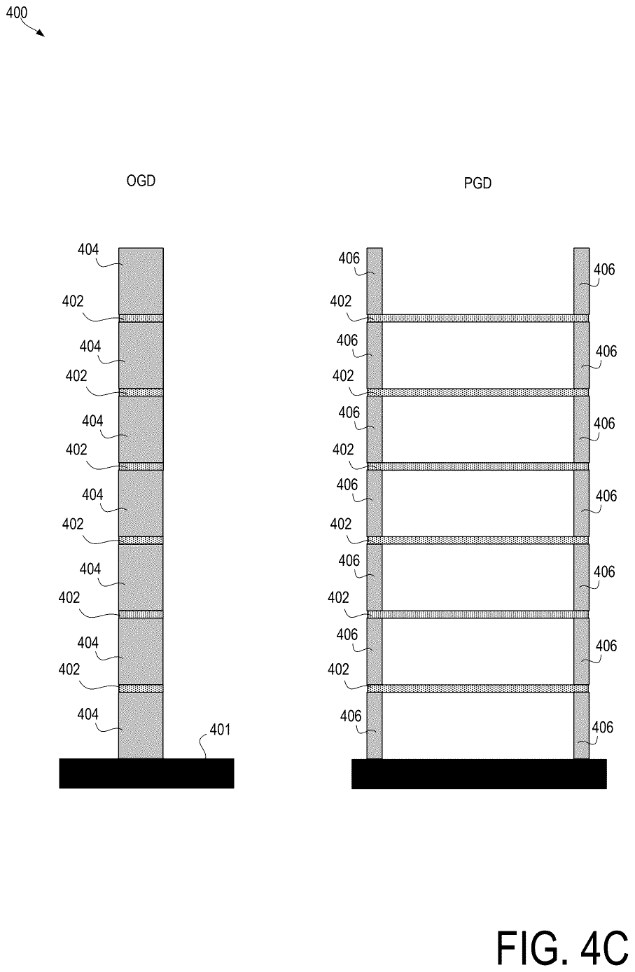

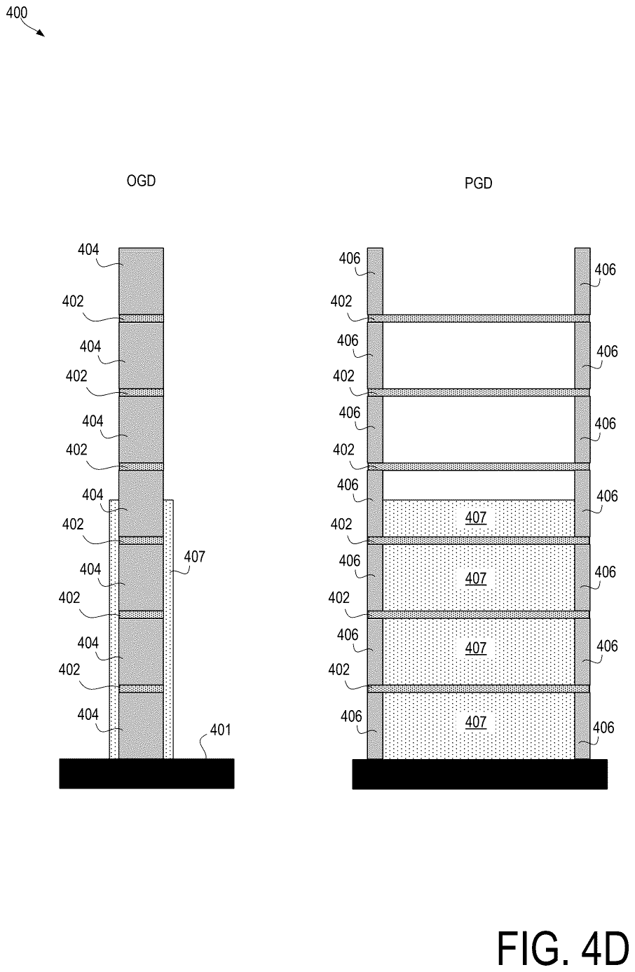

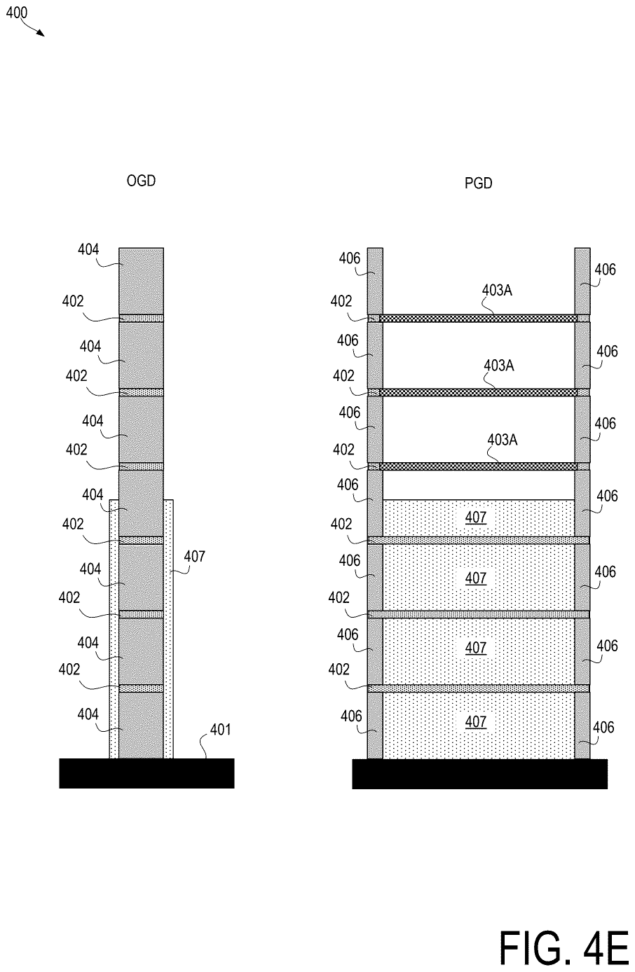

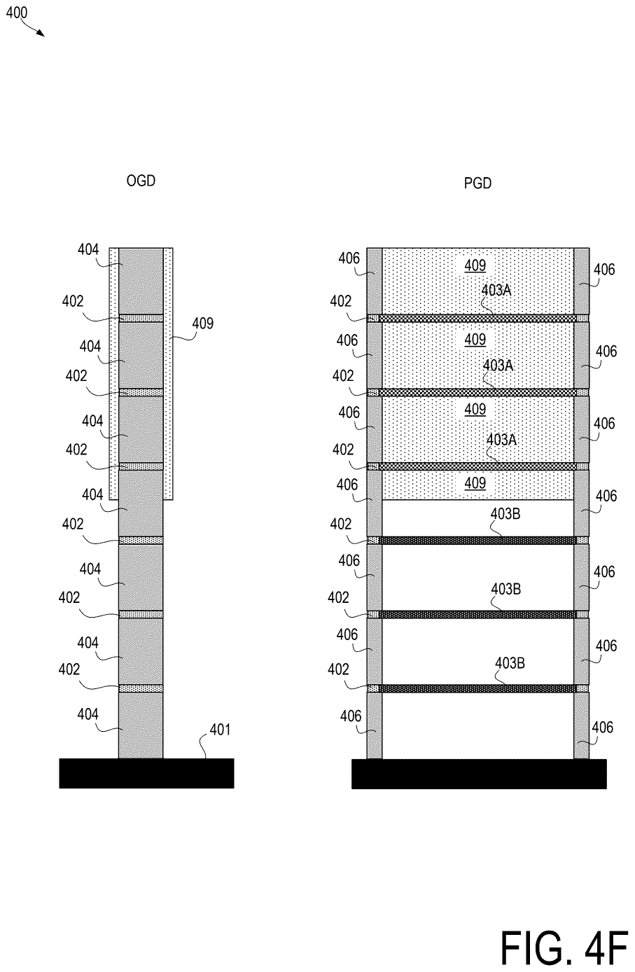

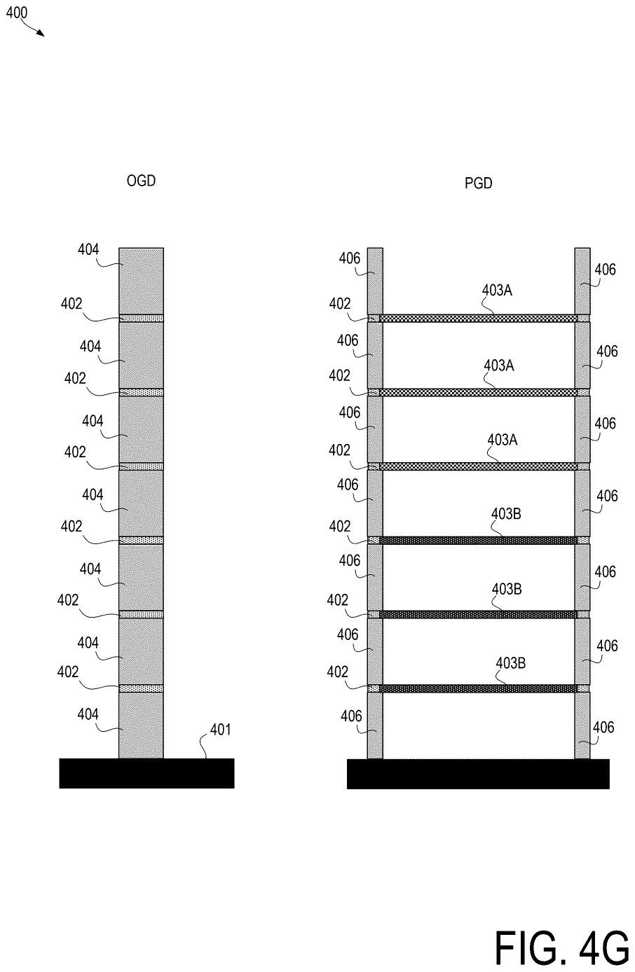

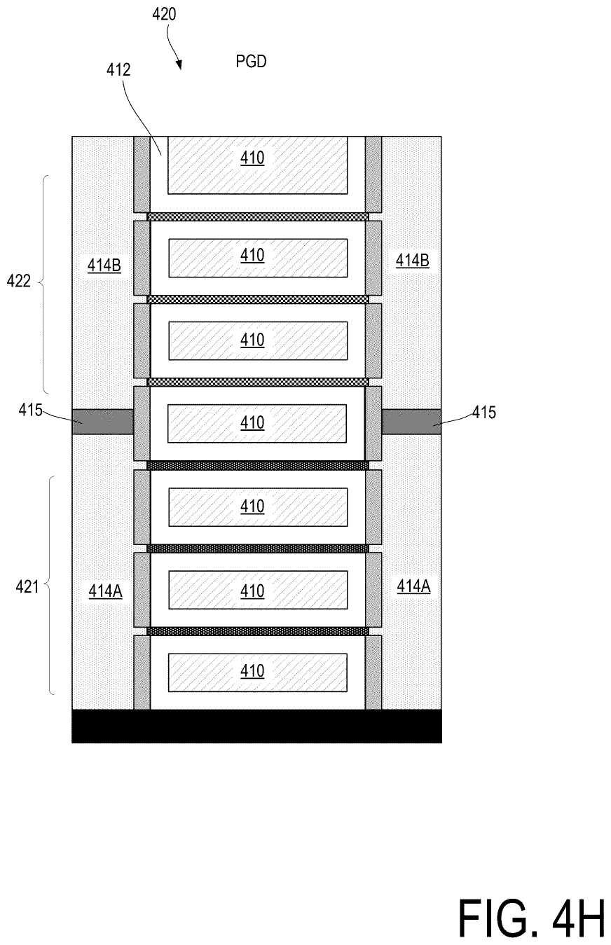

FIGS. 4A-4G illustrate another example process 400 of forming a complementary gate-all-around (GAA) transistor device in accordance with embodiments herein. FIGS. 4A-4D illustrate cross-sectional profile views as in the previous example, in both the OGD and PGD directions, as labeled. FIGS. 4A-4G show possible examples of intermediate structures during the process described below. The example process 400 may include fewer, additional, or other operations than those shown, and the operations of the process 400 can be performed in another order than shown. Moreover, some of the operations shown or described as being separate may be performed simultaneously, while some of the operations shown or described as being performed at the same time may be performed at different times. Although the process 400 illustrates the formation of a certain number of nanoribbon or nanowire channels, any number of GAA channels can be formed using the process 400.

The process 400 begins similarly to the process 300, with a superlattice stack formed on a substrate 401 as shown in FIG. 4A. The superlattice stack includes alternating layers 404 of sacrificial material and layers 402 of metal or metal oxide material. The sacrificial material layers may be formed of the same or similar materials described in the previous examples. The layers 402 may include molybdenum or tungsten, and in some embodiments, may further include oxygen. For example, the layers 402 may include a molybdenum-or tungsten-based oxide (e.g., MoOₓ or WOₓ). In the example shown, each of the layers 402 includes the same material; however, in other embodiments, the layers may include different materials (e.g., as shown in the previous example). Dimple regions 406 are then formed on opposite sides of the sacrificial material layers 404 (in the PGD direction) as shown in FIG. 4B, and the layers 402 may then be released as shown in FIG. 4C.

Then, as shown in FIG. 4D, a bottom set of the released channels may be masked off by material 407 and the top set of the released channels may be converted to 2D material. For example the stack may be heated in the presence of a chalcogen gas to convert the exposed metal/metal oxide materials in the top set of layers 402 into 2D materials. This process may be performed in the same or similar manner as described above. This may cause the exposed areas 403A in the top set of layers to convert to 2D materials as shown in FIG. 4E. In some cases, only the outer portions of the exposed channels may convert, while in other cases, the entire thickness of the exposed channels may convert. In some embodiments, portions of the top set of exposed channels between the dimple regions 406 may also convert into a 2D material. In some embodiments, the resulting 2D material layers may be etched to reduce their thickness.

The top set of channels (now converted into 2D materials) may be masked off by material 409 and the bottom set of channels may be converted to 2D material. For example, the stack may be heated in the presence of a chalcogen gas to convert the exposed metal/metal oxide materials in the bottom set of layers 402 into 2D materials. This process may be performed in the same or similar manner as described above, but with a different gas than used for the top channels to convert the bottom channels into a different 2D material. This may cause the exposed areas 403B in the top set of channel layers to convert to 2D materials, which are different from the top set of channel layers as shown in FIG. 4F. In some cases, only the outer portions of the exposed channels may convert, while in other cases, the entire thickness of the exposed channels may convert. In some embodiments, portions of the top set of exposed channels between the dimple regions 406 may also convert into a 2D material. In some embodiments, the resulting 2D material layers may be etched to reduce their thickness.

After all the channels have been converted into 2D materials, they may be released again as shown in FIG. 4G. A gate-last process or a gate-first process similar to the ones described above can then be performed to form the source/drain regions 414A, 414B for the transistors 421, 422 (which are separated by a layer 415, which may be dielectric in some embodiments or metal in other embodiments (e.g., to conductively couple the source/drain regions)), respectively, as well as the gate dielectric 412, and the gate 410 to yield the CFET device 420 of FIG. 4H, which includes n-type transistor 421 and p-type transistor 422 (or vice versa). The CFET device 420 can be implemented in a logic circuit or other type of electronic assembly or system, e.g., those described below.

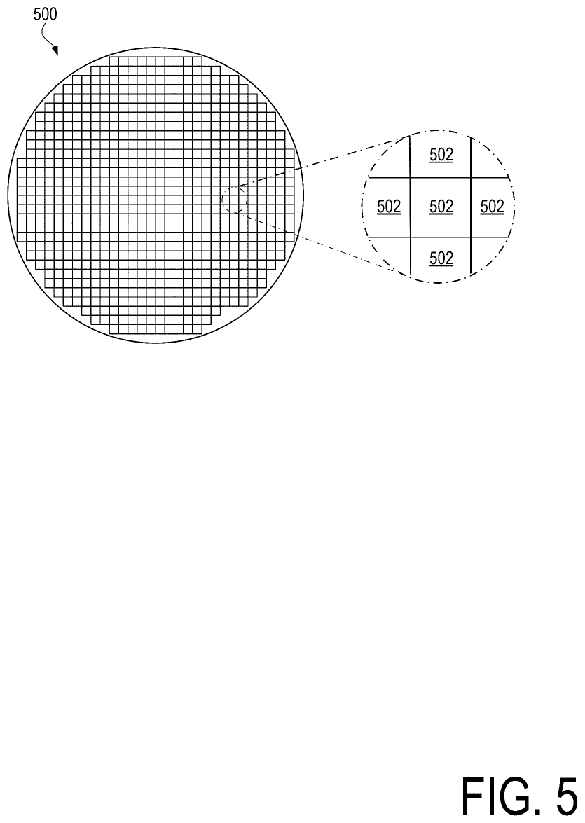

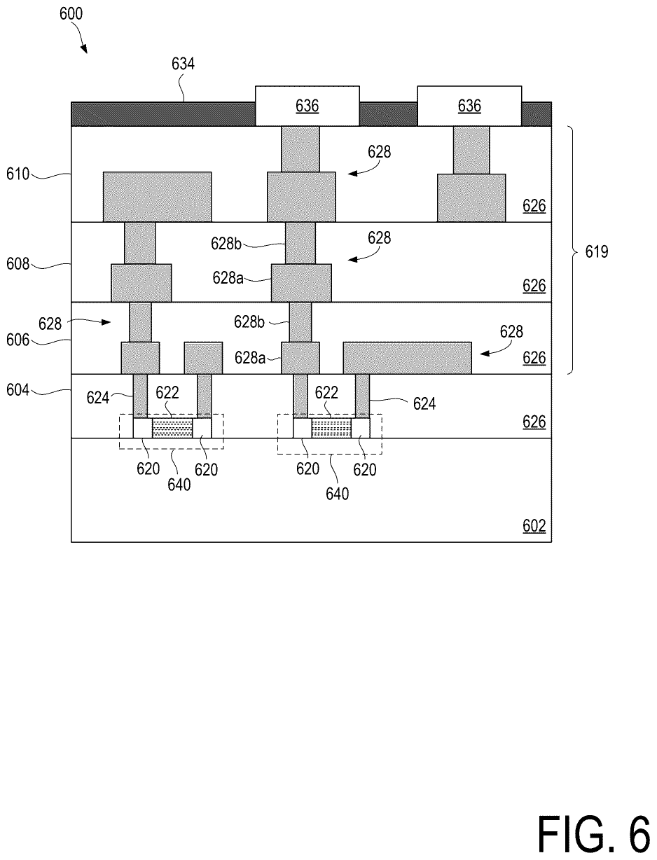

FIG. 5 is a top view of a wafer 500 and dies 502 that may include any of the embodiments disclosed herein (e.g., as any suitable ones of the transistor devices 220, 320, 420). The wafer 500 may be composed of semiconductor material and dies 502 having integrated circuit structures formed on a surface of the wafer 500. The individual dies 502 may be a repeating unit of an integrated circuit product that includes any suitable integrated circuit. After the fabrication of the semiconductor product is complete, the wafer 500 may undergo a singulation process in which the dies 502 are separated from one another to provide discrete “chips” of the integrated circuit product. The dies 502 may include one or more of any of the transistor devices 220, 320, 420 disclosed herein. The dies 502 may include one or more transistors (e.g., transistors 640 of FIG. 6, discussed below), supporting circuitry to route electrical signals to the transistors, passive components (e.g., signal traces, resistors, capacitors, or inductors), and/or any other integrated circuit components that can be fabricated on the wafer. In some embodiments, the wafer 500 or the dies 502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), logic gates (e.g., AND, OR, NAND, and NOR gates), or any other suitable circuit element. Multiple ones of these devices and components may be combined on a single die. For example, a memory array formed by multiple memory devices may be formed on the same die as a processor unit or other logic configured to store information in the memory devices or execute instructions stored in the memory array.

FIG. 6 is a cross-sectional view of an integrated circuit structure 600 that may include any of the embodiments disclosed herein (e.g., any of the transistor devices 220, 320, 420). Multiple instances of the integrated circuit structure 600 may be included in the dies 502 (FIG. 5). The integrated circuit structure 600 may be formed on a die substrate 602. The die substrate 602 may be a semiconductor substrate composed of semiconductor material including, for example, n-type or p-type materials (or a combination of both). The die substrate 602 may include, for example, a crystalline substrate formed using a bulk silicon or a silicon-on-insulator (SOI) substructure. In some embodiments, the die substrate 602 can comprise a layer of silicon on top of an SOI layer with bulk silicon below the SOI layer. In some embodiments, the die substrate 602 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 602. Although a few examples of materials from which the die substrate 602 may be formed are described here, any material that may serve as a foundation for an integrated circuit structure 600 may be used. The die substrate 602 may be part of a singulated die (e.g., dies 502 of FIG. 5) or a wafer (e.g., wafer 500 of FIG. 5).

The integrated circuit structure 600 may include device layer 604 disposed on the die substrate 602. The device layer 604 may include features of transistors 640 (e.g., metal oxide semiconductor field-effect transistors (MOSFETs)) formed on the die substrate 602. The transistors 640 may include, for example, source and drain regions (S/D regions 620), a gate 622 to control current flow between the S/D regions 620, and S/D contacts 624 to route electrical signals to and from the S/D regions 620. The transistors 640 may include additional features not depicted for the sake of clarity, such as device isolation regions, gate contacts, and the like. The transistors 640 are not limited to the type and configuration depicted in FIG. 6 and may include a wide variety of other types and configurations such as, for example, non-planar transistors, or a combination of planar and non-planar transistors. Non-planar transistors may include FinFET transistors, such as double-gate transistors or tri-gate transistors, and wrap-around or all-around gate transistors, such as nanoribbon, nanosheet, or nanowire transistors.

Returning to FIG. 6, transistors 640 may include a GAA transistor as described herein, which includes a gate 622 formed around multiple channel regions that are between S/D regions 620. The transistors 640 include a high-k gate dielectric between the gate 622 and the channel regions.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For PMOS transistors, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For NMOS transistors, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

The S/D regions 620 may be formed using an implantation/diffusion process or an etching/deposition process, for example. In the former process, dopants such as boron, aluminum, antimony, phosphorous, or arsenic may be ion-implanted into the die substrate 602 to form the S/D regions 620. An annealing process that activates the dopants and causes them to diffuse further into the die substrate 602 may follow the ion implantation process. In the latter process, the die substrate 602 may first be etched to form recesses at the locations of the S/D regions 620. An epitaxial deposition process may then be carried out to fill the recesses with material that is used to fabricate the S/D regions 620. In some implementations, the S/D regions 620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 620 may be formed using one or more alternate semiconductor materials such as germanium or a group III-V material or alloy. In further embodiments, one or more layers of metal and/or metal alloys may be used to form the S/D regions 620.

Electrical signals, such as power and/or information-carrying signals (e.g., input/output (I/O) signals, may be routed to and/or from devices (e.g., transistors 640) of the device layer 604 through one or more interconnect layers disposed on the device layer 604 (illustrated in FIG. 6 as interconnect layers 606-610). For example, electrically conductive features of the device layer 604 (e.g., the gate 622 and the S/D contacts 624) may be electrically coupled with interconnect structures 628 of the interconnect layers 606-610. The one or more interconnect layers 606-610 may form a metallization stack 619 (which can also be referred to as an “ILD stack” (inter-layer dielectric stack)) of the integrated circuit structure 600.

The interconnect structures 628 may be arranged within the interconnect layers 606-610 to route electrical signals according to a wide variety of designs; in particular, the arrangement is not limited to the particular configuration of interconnect structures 628 depicted in FIG. 6. Although a particular number of interconnect layers 606-610 is depicted in FIG. 6, embodiments of the present disclosure include integrated circuit structures having more or fewer interconnect layers than depicted.

In some embodiments, the interconnect structures 628 may include traces or lines 628a and/or vias 628b filled with an electrically conductive material such as a metal. The lines 628a may be arranged to route electrical signals in a direction of a plane that is substantially parallel with a surface of the die substrate 602 upon which the device layer 604 is formed. For example, the lines 628a may route electrical signals in a direction in and out of the page and/or in a direction across the page from the perspective of FIG. 6. The vias 628b may be arranged to route electrical signals in a direction of a plane that is substantially perpendicular to the surface of the die substrate 602 upon which the device layer 604 is formed. In some embodiments, lines 628a of different interconnect layers 606-610 are electrically coupled by vias 628b.

The interconnect layers 606-610 may include a dielectric material 626 within which the interconnect structures 628 are disposed, as shown in FIG. 6. In some embodiments, dielectric material 626 in different ones of the interconnect layers 606-610 may have different compositions; in other embodiments, the composition of the dielectric material 626 between different interconnect layers 606-610 may be the same. The device layer 604 may include a dielectric material 626 within which the transistors 640 are disposed and upon which a bottom layer of the metallization stack is located. The dielectric material 626 that is part of the device layer 604 may have a different composition than the dielectric material 626 included in the interconnect layers 606-610; in other embodiments, the composition of the dielectric material 626 in the device layer 604 may be the same as a dielectric material 626 included in any one of the interconnect layers 606-610.

A first interconnect layer 606 (which can be referred to as a Metal 1 or “M1” layer) may be formed directly on the device layer 604. In some embodiments, the first interconnect layer 606 may include lines 628a and/or vias 628b, as shown. The lines 628a of the first interconnect layer 606 may be coupled with contacts (e.g., the S/D contacts 624) of the device layer 604. The vias 628b of the first interconnect layer 606 may be coupled with the lines 628a of a second interconnect layer 608.

The second interconnect layer 608 (which can be referred to as a Metal 2 or “M2” layer) may be formed directly on the first interconnect layer 606. In some embodiments, the second interconnect layer 608 may include vias 628b to couple the lines 628a of the second interconnect layer 608 with the lines 628a of a third interconnect layer 610. Although the lines 628a and the vias 628b are structurally delineated with a line within individual interconnect layers for the sake of clarity, the lines 628a and the vias 628b may be structurally and/or materially contiguous (e.g., simultaneously filled during a dual-damascene process) in some embodiments.

The third interconnect layer 610 (which can be referred to as a Metal 3 or “M3” layer) (and additional interconnect layers, as desired) may be formed in succession on the second interconnect layer 608 according to similar techniques and configurations described in connection with the second interconnect layer 608 or the first interconnect layer 606. In some embodiments, the interconnect layers that are “higher up” in the metallization stack 619 in the integrated circuit structure 600 (i.e., farther away from the device layer 604) may be thicker than the interconnect layers that are lower in the metallization stack 619, with lines 628a and vias 628b in the higher interconnect layers being thicker than those in the lower interconnect layers.

The integrated circuit structure 600 may include a solder resist material 634 (e.g., polyimide or similar material) and conductive contacts 636 formed on the stack of interconnect layers 606-610. In FIG. 6, the conductive contacts 636 are illustrated as taking the form of bond pads. The conductive contacts 636 may be electrically coupled with interconnect structures 628 of the top-most layer in the metallization stack 619 and configured to route electrical signals between the transistors 640 and components external to the integrated circuit structure 600. For example, solder bonds may be formed on the conductive contacts 636 to mechanically and/or electrically couple an integrated circuit component comprising the integrated circuit structure 600 with another component (e.g., a printed circuit board). The integrated circuit structure 600 may include additional or alternate structures to route electrical signals from the interconnect layers 606-610; for example, the conductive contacts 636 may include other analogous features (e.g., posts) that can route the electrical signals between the transistors 640 and external components.

In some embodiments in which the integrated circuit structure 600 is part of a double-sided die, the integrated circuit structure 600 may include a second metallization stack (not shown) located on the opposite side of the die substrate 602 from the device layer 604. This second metallization stack may include multiple interconnect layers as discussed above with reference to the interconnect layers 606-610. Through-silicon vias (TSVs) that extend through the die substrate 602 can provide electrically conductive pathways from the transistors 640 to the second metallization stack and the second metallization stack can electrically couple the TSVs to additional conductive contacts (not shown) located on the opposite side of the integrated circuit structure 600 from the conductive contacts 636.

In some embodiments, TSVs extending through the die substrate 602 can be used for routing power and ground signals from conductive contacts located on the opposite side of the integrated circuit structure 600 from the conductive contacts 636 to the transistors 640 and any other components integrated into the integrated circuit structure 600, and the metallization stack 619 can be used to route information-carrying signals from the conductive contacts 636 to transistors 640 and any other components integrated into the integrated circuit structure 600. Put another way, the routing of power and ground signals to the transistors 640 can be separated (via a back-side or bottom-side metallization stack and TSVs) from the routing of information-carrying signals to the transistors. The power and ground signals are provided by a backside or bottom-side metallization stack and TSVs, and information-carrying signals are provided by a topside metallization stack (e.g., metallization stack 619).

Several integrated circuit dies may be stacked with one or more TSVs in the individual stacked dies providing connection between one of the dies to any of the other dies in the stack. For example, one or more high-bandwidth memory (HBM) integrated circuit dies can be stacked on top of a base integrated circuit die and TSVs in the HBM dies can provide connection between the individual HBM dies and the base integrated circuit die. Conductive contacts can provide additional connections between adjacent integrated circuit dies in the stack. In some embodiments, the conductive contacts can be fine-pitch solder bumps (microbumps).

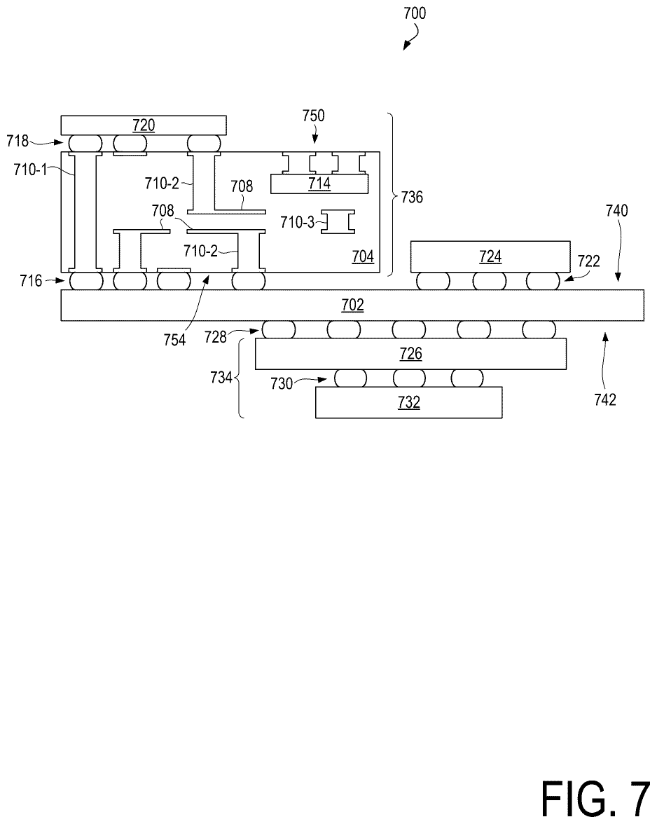

FIG. 7 is a cross-sectional view of an integrated circuit device assembly 700 that may include any of the embodiments disclosed herein. The integrated circuit device assembly 700 includes a number of components disposed on a circuit board 702 (which may be a motherboard, system board, mainboard, etc.). The integrated circuit device assembly 700 includes components disposed on a first face 740 of the circuit board 702 and a second face 742 of the circuit board 702, the second face 742 opposing the first face 740. Generally, components may be disposed on either or both of the first face 740 and the second face 742 of the circuit board 702.

In some embodiments, the circuit board 702 may be a printed circuit board (PCB) including multiple metal (or interconnect) layers separated from one another by layers of dielectric material and interconnected by electrically conductive vias. The individual metal layers comprise conductive traces. The metal layers may be formed in a desired pattern to route electrical signals between the components electrically coupled to the circuit board 702. In other embodiments, the circuit board 702 may be a non-PCB substrate.

The integrated circuit device assembly 700 illustrated in FIG. 7 includes a package-on-interposer structure 736 coupled to the first face 740 of the circuit board 702 by coupling components 716. The coupling components 716 may electrically and mechanically couple the package-on-interposer structure 736 to the circuit board 702 and may include solder balls (as shown in FIG. 7), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. (Thus, a coupling component may comprise a conductive contact.)

The package-on-interposer structure 736 may include an integrated circuit component 720 coupled to an interposer 704. The interposer 704 may provide an intervening substrate used to bridge the circuit board 702 and the integrated circuit component 720. The integrated circuit component 720 is coupled to the interposer 704 by coupling components 718. The coupling components 718 may take any suitable form, such as the forms discussed above with reference to the coupling components 716. Although FIG. 7 shows just one integrated circuit component attached to the interposer, multiple integrated circuit components may be coupled to the interposer 704. Additional interposers may be coupled to the interposer 704.

The integrated circuit component 720 may be a packaged or unpacked integrated circuit product that includes one or more integrated circuit dies (e.g., the die 502 of FIG. 5, a die comprising the integrated circuit structure 600 of FIG. 6) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one unpackaged example of an integrated circuit component 720, a single monolithic integrated circuit die comprises solder bumps attached to contacts on the die. The solder bumps allow the die to be directly attached to the interposer 704. The integrated circuit component 720 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 720 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 720 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 720 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 704 may spread connections to a wider or narrower pitch or reroute a connection to a different connection. For example, the interposer 704 may couple coupling components 718 having a first pitch to coupling components 716 having a wider pitch than the first pitch. In the embodiment illustrated in FIG. 7, the integrated circuit component 720 and the circuit board 702 are attached to opposing sides of the interposer 704. In other embodiments, the integrated circuit component 720 and the circuit board 702 may be attached to a same side of the interposer 704. In some embodiments, three or more components may be interconnected by way of the interposer 704.

In some embodiments, the interposer 704 may be formed as a PCB, including multiple metal layers separated from one another by layers of dielectric material and interconnected by electrically conductive vias. In some embodiments, the interposer 704 may be formed of an epoxy resin, a fiberglass-reinforced epoxy resin, an epoxy resin with inorganic fillers, a ceramic material, or a polymer material such as polyimide. In some embodiments, the interposer 704 may be formed of alternate rigid or flexible materials that may include the same materials described above for use in a semiconductor substrate, such as silicon, germanium, and other group III-V and group IV materials. The interposer 704 may include metal interconnects 708 and vias, including but not limited to through hole vias 710-1 (that extend from a first face 750 of the interposer 704 to a second face 754 of the interposer 704), blind vias 710-2 (that extend from the first face 750 or the second face 754 of the interposer 704 to an internal metal layer), and buried vias 710-3 (that connect internal metal layers).

In some embodiments, the interposer 704 can comprise a silicon interposer. Through silicon vias (TSV) extending through the silicon interposer can connect connections on a first face of a silicon interposer to an opposing second face of the silicon interposer. In some embodiments, an interposer 704 comprising a silicon interposer can further comprise one or more routing layers to route connections on a first face of the interposer 704 to an opposing second face of the interposer 704.

In some embodiments the interposer 704, as well as the circuit board 702, can comprise an amorphous solid layer of glass (which can be referred to a glass core or glass substrate). In some embodiments, the layer of glass can comprise silica (comprising silicon dioxide (SiO₂)), fused silica, aluminosilicate (comprising aluminum oxide (Al₂O₃) and silicon dioxide), borosilicate (comprising silicon dioxide and boron trioxide (B₂O₃)), or alumino-borosilicate (comprising aluminum oxide, silicon dioxide, and boron trioxide). In some embodiments, the layer of glass can comprise one or more of the following additives: aluminum oxide, boron trioxide, magnesium oxide (MgO), calcium oxide (CaO), strontium oxide (SrO), barium oxide (BaO), tin(IV) oxide (SnO₂), nitrous oxide (Na₂O), potassium oxide (K₂O), diphosphorous trioxide (P₂O₃), zirconium dioxide (ZrO₂), lithium oxide (Li₂O), titanium, and zinc. In some embodiments, the layer of glass can comprise silicon and oxygen, as well as one or more of aluminum, boron, magnesium, calcium, barium, tin, sodium, potassium, strontium, phosphorous, zirconium, lithium, titanium, and zinc. In some embodiments, the layer of glass comprises at least 23 percent silicon by weight, at least 26 percent oxygen by weight, and at least five percent aluminum by weight. In some embodiments, the layer of glass does not include an organic adhesive or an organic material. For example, the layer of glass is not a substrate or a board comprising glass fibers and an epoxy binder, such as a printed circuit board (PCB) comprising multiple metal (or interconnect) layers separated from one another by layers of dielectric material (e.g., FR-4 or other fiberglass-reinforced epoxy laminate) and interconnected by electrically conductive vias.

In some embodiments, the glass layer has a thickness in the range of about 50 microns to about 1.4 millimeters. In some embodiments, the glass layer is or is part of a multi-layer glass substrate (a coreless substrate). Individual glass layers in a multi-layer glass substrate can have a thickness in the range of about 25 microns to about 50 microns. In some embodiments, a glass layer can have a length in the range of about 10 millimeters to about 250 millimeters on a side (e.g., can have an area in the range of about 10 mm×10 mm to about 250 mm×250 mm). In some embodiments, the glass layer comprises a rectangular prism volume with sections or portions (e.g., through-glass vias) removed and filled with other metals (e.g., metal).

In some embodiments, redistribution layers (RDL) can be located on either or both sides of the glass layer to provide electrically conductive paths from top and/or bottom surfaces of the interposer 704 or circuit board 702 to the glass layer. The glass layer can comprise through-glass vias (TGVs) that extend through the glass layer to provide electrically conductive paths through the glass core, glass substrate, or glass layer.

The interposer 704 may further include embedded devices 714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 704. The package-on-interposer structure 736 may take the form of any of the package-on-interposer structures known in the art.

The integrated circuit device assembly 700 may include an integrated circuit component 724 coupled to the first face 740 of the circuit board 702 by coupling components 722. The coupling components 722 may take the form of any of the embodiments discussed above with reference to the coupling components 716, and the integrated circuit component 724 may take the form of any of the embodiments discussed above with reference to the integrated circuit component 720.

The integrated circuit device assembly 700 illustrated in FIG. 7 further includes a package-on-package structure 734 coupled to the second face 742 of the circuit board 702 by coupling components 728. The package-on-package structure 734 may include an integrated circuit component 726 and an integrated circuit component 732 coupled together by coupling components 730 such that the integrated circuit component 726 is disposed between the circuit board 702 and the integrated circuit component 732. The coupling components 728 and 730 may take the form of any of the embodiments of the coupling components 716 discussed above, and the integrated circuit components 726 and 732 may take the form of any of the embodiments of the integrated circuit component 720 discussed above. The package-on-package structure 734 may be configured in accordance with any of the package-on-package structures known in the art.

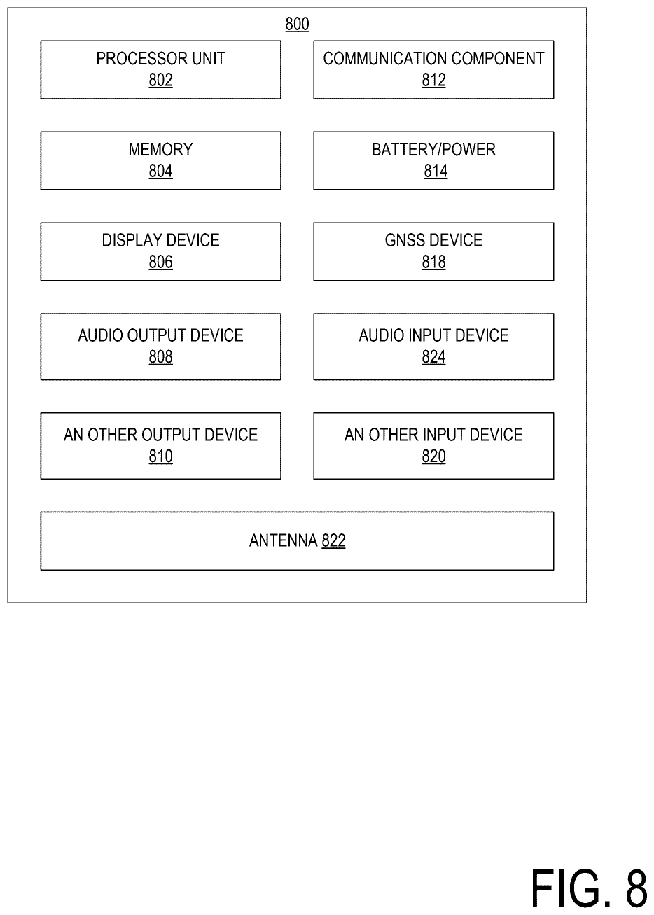

FIG. 8 is a block diagram of an example electrical device 800 that may include any of the embodiments disclosed herein. For example, any suitable ones of the components of the electrical device 800 may include one or more of the integrated circuit device assembly 700, integrated circuit component 720, or integrated circuit structure 600, integrated circuit dies 502 disclosed herein. A number of components are illustrated in FIG. 8 as included in the electrical device 800, but any one or more of these components may be omitted or duplicated, as suitable for the application. In some embodiments, some or all of the components included in the electrical device 800 may be attached to one or more motherboards mainboards, or system boards. In some embodiments, one or more of these components are fabricated onto a single system-on-a-chip (SoC) die.

Additionally, in various embodiments, the electrical device 800 may not include one or more of the components illustrated in FIG. 8, but the electrical device 800 may include interface circuitry for coupling to the one or more components. For example, the electrical device 800 may not include a display device 806, but may include display device interface circuitry (e.g., a connector and driver circuitry) to which a display device 806 may be coupled. In another set of examples, the electrical device 800 may not include an audio input device 824 or an audio output device 808, but may include audio input or output device interface circuitry (e.g., connectors and supporting circuitry) to which an audio input device 824 or audio output device 808 may be coupled.

The electrical device 800 may include one or more processor units 802. As used herein, the terms “processor unit,” “processing unit,” or “processor” may refer to any device or portion of a device that processes electronic data from registers and/or memory to transform that electronic data into other electronic data that may be stored in registers and/or memory. The one or more processor units 802 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 800 may include a memory 804, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 804 may include memory that is located on the same integrated circuit die as the one or more processor units 802. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments of the electrical device 800, a first one of the one or more processor units 802 can be heterogeneous or asymmetric to a second one of the one or more processor units 802 in the electrical device 800. There can be a variety of differences between the one or more processor units 802 in a system in terms of a spectrum of metrics of merit including architectural, microarchitectural, thermal, power consumption characteristics, and the like. These differences can effectively manifest themselves as asymmetry and heterogeneity among the one or more processor units 802 in the electrical device 800.

In some embodiments, the electrical device 800 may include a communication component 812. For example, the communication component 812 can manage wireless communications for the transfer of data to and from the electrical device 800. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP 2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 812 may operate in accordance with other wireless protocols in other embodiments. The electrical device 800 may include an antenna 822 to facilitate wireless communications and/or to receive other wireless communications (such as AM or FM radio transmissions).

In some embodiments, the communication component 812 may manage wired communications, such as electrical, optical, or any other suitable communication protocols (e.g., IEEE 802.3 Ethernet standards). In some embodiments, the electrical device 800 comprises multiple communication components. For instance, a first communication component may be dedicated to shorter-range wireless communications such as Wi-Fi or Bluetooth, and a second communication component may be dedicated to longer-range wireless communications such as global positioning system (GPS), EDGE, GPRS, CDMA, WiMAX, LTE, EV-DO, or others. In some embodiments, a first communication component may be dedicated to wireless communications, and a second communication component may be dedicated to wired communications.

The electrical device 800 may include battery/power circuitry 814. The battery/power circuitry 814 may include one or more energy storage devices (e.g., batteries or capacitors) and/or circuitry for coupling components of the electrical device 800 to an energy source separate from the electrical device 800 (e.g., AC line power).

The electrical device 800 may include a display device 806 (or corresponding interface circuitry, as discussed above). The display device 806 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 800 may include an audio output device 808 (or corresponding interface circuitry, as discussed above). The audio output device 808 may include any embedded or wired or wirelessly connected external device that generates an audible indicator, such as speakers, headsets, or earbuds.

The electrical device 800 may include an audio input device 824 (or corresponding interface circuitry, as discussed above). The audio input device 824 may include any embedded or wired or wirelessly connected device that generates a signal representative of a sound, such as microphones, microphone arrays, or digital instruments (e.g., instruments having a musical instrument digital interface (MIDI) output). The electrical device 800 may include a Global Navigation Satellite System device (GNSS) (or corresponding interface circuitry, as discussed above), such as a Global Positioning System (GPS) device. The GNSS device 818 may be in communication with a satellite-based system and may determine a geolocation of the electrical device 800 based on information received from one or more GNSS satellites, as known in the art.

The electrical device 800 may include another output device 810 (or corresponding interface circuitry, as discussed above). Examples of the other output device 810 may include an audio codec, a video codec, a printer, a wired or wireless transmitter for providing information to other devices, or an additional storage device.

The electrical device 800 may include another input device 820 (or corresponding interface circuitry, as discussed above). Examples of the other input device 820 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 800 may have any form factor, such as a hand-held or mobile electrical device (e.g., a cell phone, a smartphone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console), a desktop electrical device, a server, a rack-level computing solution (e.g., blade, tray, or sled computing system), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 800 may be any other electronic device that processes data. In some embodiments, the electrical device 800 may comprise multiple discrete physical components. Given the range of devices that the electrical device 800 can be manifested as in various embodiments, in some embodiments, the electrical device 800 can be referred to as a computing device or a computing system.

As used herein, “first,” “second,” “third,” and the like describe a common object and indicate different instances of like objects being referred to. Such adjectives do not imply objects so described must be in a given sequence, either temporally or spatially, in ranking, or any other manner.

“Connected” may indicate elements are in direct physical or electrical contact with each other and “coupled” may indicate elements cooperate or interact with each other, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, layers, faces, or features that are referred to as being substantially parallel can refer to layers, faces, or features that are within a few degrees of being parallel with each other, and layers, faces, or features that are referred to as being substantially perpendicular to each other can refer to features that are within +/−15 degrees of being perpendicular to each other. As another example, a device that is substantially the same as another device can refer to the devices having the same or very similar device structures and/or features.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components. In addition, as used herein, the term “adjacent” refers to layers or components that are arranged next to each other (e.g., side-by-side, top and bottom). For example, with reference to FIG. 2B, each layer 202 is located on a layer 204, and each dimple 206 is adjacent to a layer 204.

Certain terminology may also be used herein for the purpose of reference only, and thus are not intended to be limiting. For example, terms such as “upper,” “lower,” “above,” “below,” “bottom,” and “top” refer to directions in the Figures to which reference is made. Terms such as “front,” “back,” “rear,” and “side” describe the orientation and/or location of layers, components, portions of components, etc., within a consistent but arbitrary frame of reference, which is made clear by reference to the text and the associated Figures describing the layers, component, portions of components, etc. under discussion. Such terminology may include the words specifically mentioned above, derivatives thereof, and words of similar import.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

As used herein, the phrase “electrically coupled” refers to the presence of one or more electrically conductive paths between components that are recited as being electrically coupled. For example, with reference to FIG. 6, electrically conductive features of the device layer 604 (e.g., the gate 622 and the S/D contacts 624) may be electrically coupled with interconnect structures 628 of the interconnect layers 606-610, and lines 628a of different interconnect layers 606-610 are electrically coupled by vias 628b.

As used in this application and the claims, a list of items joined by the term “and/or” can mean any combination of the listed items. For example, the phrase “A, B, and/or C” can mean A; B; C; A and B; A and C; B and C; or A, B and C. As used in this application and the claims, a list of items joined by the term “at least one of” can mean any combination of the listed terms. For example, the phrase “at least one of A, B, or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B, and C” can mean A; B; C; A and B; A and C; B and C; or A, B, and C. Further, as used in this application and the claims, the phrase “A and one of B, C, and D” can mean “A and B”, “A and C”, or “A and D”.

As used in this application and the claims, the phrase “individual of” or “respective of” following by a list of items recited or stated as having a trait, feature, etc. means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

In the above description, specific details have been set forth, but embodiments of the technologies described may be practiced without each of these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics. Embodiments of the present disclosure may have some, all, or none of the features described in the examples described herein.

The following examples pertain to additional embodiments of technologies disclosed herein.

Example 1 is an integrated circuit structure comprising: a gate-all-around (GAA) transistor comprising: a plurality of channel regions comprising a transition metal dichalcogenide material; a gate region around each of the channel regions; gate dielectric regions between each channel region and the gate region; a source region on a first side of the channel regions; and a drain region on a second side of the channel regions opposite the first side.

Example 2 includes the integrated circuit structure of Example 1, wherein each channel region comprises molybdenum and one of sulfur, selenium, and tellurium.

Example 3 includes the integrated circuit structure of Example 1, wherein each channel region comprises tungsten and one of sulfur and selenium.

Example 4 includes the integrated circuit structure of any one of Examples 1-3, wherein the GAA transistor comprises dielectric dimple regions adjacent to each gate dielectric region.

Example 5 includes the integrated circuit structure of Example 4, wherein each channel region is partially between two dielectric dimple regions.

Example 6 includes the integrated circuit structure of any one of Examples 1-5, wherein the plurality of channels comprises first channel regions comprising a first transition metal dichalcogenide material and second channel regions above the first channel regions, the second channel regions comprising a second transition metal dichalcogenide material.

Example 7 includes the integrated circuit structure of Example 6, wherein the first channel regions comprise molybdenum and one of sulfur, selenium, and tellurium, and the second channel regions comprise tungsten and one of sulfur and selenium.

Example 8 is an integrated circuit component comprising the integrated circuit structure of any one of Examples 1-7.

Example 9 is an integrated circuit device assembly comprising the integrated circuit component of Example 8 and a circuit board.

Example 10 is a system comprising: a device comprising a plurality of gate-all-around (GAA) transistors, the GAA transistors comprising transition metal dichalcogenide material (2D material) channels; and one or more memory devices.

Example 11 includes the system of Example 10, wherein the 2D material channels comprise molybdenum and sulfur, selenium, or tellurium.

Example 12 includes the system of Example 10, wherein the 2D material channels comprise tungsten and sulfur or selenium.

Example 13 includes the system of any one of Examples 10-12, wherein the device comprises a complementary field effect transistor (CFET) GAA transistor comprising first 2D material channels comprising a first transition metal dichalcogenide material and second 2D material channels comprising a second transition metal dichalcogenide material.

Example 14 is a method comprising: forming a superlattice stack comprising alternating first layers and second layers, the first layers comprising a metal and the second layers comprising, e.g., silicon and one of oxygen and nitrogen; forming dimple regions adjacent to the second layers, the dimple regions comprising dielectric material; removing the second layers; converting at least a portion of each respective first layer into a transition metal dichalcogenide material; forming source/drain regions adjacent opposite ends of the first layers; forming gate dielectric layers around the first layers; and forming a gate material around the gate dielectric layers.

Example 15 includes the method of Example 14, wherein converting at least a portion of the respective first layers into transition metal dichalcogenide material comprises heating the stack in a chalcogen gas.

Example 16 includes the method of Example 15, wherein the chalcogen gas comprises hydrogen and one of sulfur, tellurium, and selenium.

Example 17 includes the method of Example 15 or 16, wherein the chalcogen gas comprises an organometallic comprising one of sulfur, tellurium, and selenium.

Example 18 includes the method of Example 17, wherein the chalcogen gas comprises one of di-tert-butyl sulfide, di-isopropyl selenide, and diethyl telluride.

Example 19 includes the method of any one of Examples 14-15, further comprising removing distal ends of the first layers before forming the source/drain regions.

Example 20 includes the method of any one of Examples 14-16, wherein the first layers comprise molybdenum or tungsten.

Example 21 includes the method of Example 20, wherein the first layers further comprise oxygen.

Example 22 is a method comprising: forming a superlattice stack comprising a first portion and a second portion, the first portion comprising alternating first layers and second layers and the second portion comprising alternating third layers and fourth layers, the first layers comprising a first metal, the third layers comprising a second metal, and the second layers and fourth layers comprising silicon and one of oxygen and nitrogen; forming dimple regions adjacent to the second layers and adjacent to the fourth layers, the dimple regions comprising dielectric material; removing the second layers and the fourth layers; converting at least a portion of each respective first layer into a first transition metal dichalcogenide material; converting at least a portion of each respective third layer into a second transition metal dichalcogenide material; forming source/drain regions adjacent opposite ends of the first layers and the third layers; forming gate dielectric layers around the first layers and the third layers; and forming a gate material around the gate dielectric layers.

Example 23 includes the method of Example 22, wherein converting at least a portion of each respective first layer into the first transition metal dichalcogenide material and converting at least a portion of each respective third layer into the second transition metal dichalcogenide material comprises heating the stack in a chalcogen gas.

Example 24 includes the method of Example 23, wherein the chalcogen gas comprises hydrogen and one of sulfur, tellurium, and selenium.

Example 25 includes the method of Example 23, wherein the chalcogen gas comprises an organometallic comprising one of sulfur, tellurium, and selenium.

Example 26 includes the method of Example 25, wherein the chalcogen gas comprises one of di-tert-butyl sulfide, di-isopropyl selenide, and diethyl telluride.

Example 27 includes the method of any one of Examples 22-26, wherein the first layers comprise molybdenum and the third layers comprise tungsten.

Example 28 is a method comprising: forming a superlattice stack comprising alternating first layers and second layers, the first layers comprising a metal and the second layers comprising, e.g., silicon and one of oxygen and nitrogen; forming dimple regions adjacent to the second layers, the dimple regions comprising dielectric material; removing the second layers; masking a first set of the first layers; converting at least a portion of each respective first layer of a second set of the first layers into a first transition metal dichalcogenide material; masking the second set of the first layers; converting at least a portion of each respective first layer of the first set into a second transition metal dichalcogenide material; forming source/drain regions adjacent opposite ends of the first layers; forming gate dielectric layers around the first layers; and forming a gate material around the gate dielectric layers.

Example 29 includes the method of Example 28, wherein converting at least a portion of each respective first layer of the second set into the first transition metal dichalcogenide material comprises heating the stack in a first chalcogen gas, and converting at least a portion of each respective first layer of the first set into the second transition metal dichalcogenide material comprises heating the stack in a second chalcogen gas.

Example 30 includes the method of Example 29, wherein the first chalcogen gas is different from the second chalcogen gas.

Example 31 includes the method of Example 29 or 30, wherein the first chalcogen gas or the second chalcogen gas comprises hydrogen and one of sulfur, tellurium, and selenium.

Example 32 includes the method of Example 29 or 30, wherein the first chalcogen gas or the second chalcogen gas comprises an organometallic comprising one of sulfur, tellurium, and selenium.

Example 33 includes the method of Example 32, wherein the chalcogen gas comprises one of di-tert-butyl sulfide, di-isopropyl selenide, and diethyl telluride.

Example 34 includes the method of any one of Examples 28-33, wherein the first layers comprise molybdenum or tungsten.

Example 35 includes the method of Example 34, wherein the first layers further comprise oxygen.

Example 36 is an apparatus or product produced by the methods of any one of Examples 14-35.

1. An integrated circuit structure comprising:
a gate-all-around (GAA) transistor comprising:
a plurality of channel regions comprising a transition metal dichalcogenide material;
a gate region around each of the channel regions;
gate dielectric regions between each channel region and the gate region;
a source region on a first side of the channel regions; and
a drain region on a second side of the channel regions opposite the first side.

2. The integrated circuit structure of claim 1, wherein each channel region comprises molybdenum and one of sulfur, selenium, and tellurium.

3. The integrated circuit structure of claim 1, wherein each channel region comprises tungsten and one of sulfur and selenium.

4. The integrated circuit structure of claim 1, wherein the GAA transistor comprises dielectric dimple regions adjacent to each gate dielectric region.

5. The integrated circuit structure of claim 4, wherein each channel region is partially between two dielectric dimple regions.

6. The integrated circuit structure of claim 1, wherein the plurality of channels comprises first channel regions comprising a first transition metal dichalcogenide material and second channel regions above the first channel regions, the second channel regions comprising a second transition metal dichalcogenide material.

7. The integrated circuit structure of claim 6, wherein the first channel regions comprise molybdenum and one of sulfur, selenium, and tellurium, and the second channel regions comprise tungsten and one of sulfur and selenium.

8. An integrated circuit component comprising the integrated circuit structure of claim 1.

9. An integrated circuit device assembly comprising the integrated circuit component of claim 8 and a circuit board.

10. A system comprising:
a device comprising a plurality of gate-all-around (GAA) transistors, the GAA transistors comprising transition metal dichalcogenide material (2D material) channels; and
one or more memory devices.

11. The system of claim 10, wherein the 2D material channels comprise molybdenum and sulfur, selenium, or tellurium.

12. The system of claim 10, wherein the 2D material channels comprise tungsten and sulfur or selenium.

13. The system of claim 10, wherein the device comprises a complementary field effect transistor (CFET) GAA transistor comprising first 2D material channels comprising a first transition metal dichalcogenide material and second 2D material channels comprising a second transition metal dichalcogenide material.

14. A method comprising:
forming a superlattice stack comprising alternating first layers and second layers, the first layers comprising a metal;
forming dimple regions adjacent to the second layers, the dimple regions comprising dielectric material;
removing the second layers;
converting at least a portion of each respective first layer into a transition metal dichalcogenide material;
forming source/drain regions adjacent opposite ends of the first layers;
forming gate dielectric layers around the first layers; and
forming a gate material around the gate dielectric layers.

15. The method of claim 14, wherein converting at least a portion of the respective first layers into transition metal dichalcogenide material comprises heating the stack in a chalcogen gas.

16. The method of claim 15, wherein the chalcogen gas comprises hydrogen and one of sulfur, tellurium, and selenium.

17. The method of claim 15, wherein the chalcogen gas comprises an organometallic comprising one of sulfur, tellurium, and selenium.

18. The method of claim 14, further comprising removing distal ends of the first layers before forming the source/drain regions.

19. The method of claim 14, wherein the first layers comprise molybdenum or tungsten.

20. The method of claim 19, wherein the first layers further comprise oxygen.
